(19) United States
(12) Patent Application Publication
(10) Pub. No.: US 2004/0259004 A1
(43) Pub. Date: Dec. 23, 2004

(54) Method for fabricating a resist mask for patterning semiconductor substrates

(76) Inventors: Odo Wunnicke, Dresden (DE); Lutz Wetzig, Gro dittmannsdorf (DE); Nadja Hermsdorf, Dusseldorf (DE); Cornelia Bellmann, Dresden (DE); Karina Grundke, Dresden (DE); Manfred Stamm, Pesterwitz (DE)

Correspondence Address: SLATER & MATSIL, L.L.P., 17950 PRESTON RD, SUITE 1000, DALLAS, TX, 75252-5793, US

(21) Appl. No.: 10/781,920

(22) Filed: Feb. 20, 2004

(30) Foreign Application Priority Data
Feb. 21, 2003 (DE) 103 07 523.2

(51) Int. Cl. G03F 9/00

(52) U.S. Cl. 430/5; 430/322; 430/331

(57) ABSTRACT

A method for fabricating patterned resist masks. Firstly, a photoresist film is applied on a semiconductor substrate in a customary manner, which photoresist film is then exposed by means of customary techniques. In the development step, a rinsing medium containing a cationic surfactant is used. If the patterned resist is dried after development, the sidewalls of the resist webs are rendered hydrophobic by the cationic surfactant, so that the contact angle can be increased to values of approximately 90°, reducing capillary forces acting on the webs of the patterned resist to approximately zero. As a result, even in the case of single-layer resist films, the line width of the webs can be reduced without a line collapse being observed.

### BACKGROUND

### FIELD OF THE INVENTION

The present invention relates generally to semiconductor processing and more particularly to a method for fabricating a resist mask for patterning semiconductor substrates.

### BACKGROUND OF THE INVENTION

Microchips are fabricated in a multiplicity of work steps in which, within a small section of the surface of a substrate, usually a silicon wafer, changes are made in a targeted manner. Such target changes include introduction of trenches for deep trench capacitors into the substrate, and thin interconnects and electrode deposition on the substrate surface. In order to be able to produce such small structures, firstly a mask is produced on the substrate surface, so that those regions to be processed are uncovered, while the other regions are protected by the material of the mask. After processing, the mask is removed from the substrate surface, for example by oxidative “ashing”. The mask is produced by firstly applying a thin layer of a photoresist containing a film-forming polymer and a photosensitive compound. The resist film is subsequently exposed, using a partially light-transmissive mask, for instance, through which the structure is imaged on the resist film. The photoresist film undergoes a chemical change in the exposed regions, as a result of which it is possible to differentiate between exposed and unexposed sections of the imaged structure. The smallest feature size that can be produced (CD, the critical dimension) is essentially determined by the wavelength of the radiation used for the exposure.

A series of methods have already been developed for fabricating patterned resists, using two fundamental groups of photoresists.

In the case of positive photoresists, the exposed regions are stripped in the development step and form trenches in the patterned photoresist, while the unexposed regions remain on the substrate and form web-like structures (“webs”) of the patterned resist. In the case of negative photoresists, in contrast to the positive resists, the exposed part of the resist remains on the substrate, while the unexposed part is removed by the developer solution. In the case of negative photoresist, the difference in the solubility of exposed and unexposed photoresists is achieved by virtue of the fact that the exposure initiates a chemical reaction through which the photoresist is crosslinked and thus becomes insoluble in a developer solution.

In the case of positive resists, the photoresist comprises, for example, a polymer containing polar groups, for example carboxyl groups, which are protected with an acid-labile nonpolar group, so that the polymer overall contains nonpolar properties. Furthermore, the photoresist contains a photoacid by means of which a strong acid is liberated during exposure. This acid cleaves the acid-labile groups at the polymer, so that polar groups are liberated. In the exposed regions, the polymer therefore acquires polar properties, so that it can be stripped in a development step using a polar developer. In the unexposed regions, in which the polymer has retained its nonpolar properties, the resist remains on the substrate and forms a mask.

The patterned photoresist generally serves as a mask for further processes, such as dry etching processes. In this case, the structure produced in the photoresist is transferred into a substrate arranged below the resist with the aid of a suitable plasma. This requires the photoresist to have a higher stability with respect to the plasma than the substrate, so that the substrate is etched as selectively as possible with respect to the photoresist. Typically, however, the etching process also removes the material of the mask to a small extent. In order that areas of the substrate that are not to be etched are still protected sufficiently by photoresist against a plasma attack, even toward the end of the etching process, it is necessary, therefore, that the photoresist layer have a minimum thickness. In this case, the required thickness is dependent on the substrate and also on the plasma used. The more resistive the substrate is with respect to the plasma, or the deeper the structure to be formed during plasma etching, the greater is the layer thickness of the resist film required.

At the present time, single-layer resist systems are most commonly used to produce extremely small structures. These systems comprise a photoresist that is deposited on an antireflection layer in order to reduce interference effects in the photoresist. After the exposure of the photoresist film, hydrous developers are typically used which strip polar components of the photoresist layer. At the end of development, the developer is removed from the surface by rinsing with water. The water is spun off from the surface of the wafer and water residues that have remained in the patterned resist are subsequently evaporated. As a result of the small distance between adjacent webs, capillary forces act on the webs during the evaporation of the water. As a result of irregularities which occur during the evaporation of the water or as a result of local variation of the distances between webs, capillary forces of different magnitudes may act on the sidewalls of the webs. This may cause the webs to fall over during the drying process. This process is also referred to as line collapse. Given a constant width of a resist feature, the thickness of the photoresist layer determines the ratio of height to width (aspect ratio) of the feature. As the aspect ratio increases, the mechanical stability of the webs decreases, thereby increasing the risk of the webs collapsing during drying.

As the density of the structures arranged on a microchip increases, the line width of said structures also decreases. For example, a resolution of structures having a feature size of down to 65 nm is required for the fabrication of DRAMs by 2007. For the further development of DRAMs, a resolution of structures down to about 22 nm is expected by 2016. In order to obtain a low defect rate in the fabrication of microchips, the thickness of the photoresist layer must therefore likewise be reduced, as the line width decreases, in order to ensure stable webs. The possibility of line collapse thus limits the maximum photoresist thickness that can be used for a given minimum linewidth, or, given a specific minimum resist film thickness, the minimum linewidth of the webs.

As an alternative to single-layer resist systems, work is also being carried out to develop multilayer resist systems and also to develop so-called hard masks. In the case of the latter methods, extremely thin photoresist films are applied to a layer of a material from which the mask is intended to be fabricated. For the patterning of the mask layer, firstly the photoresist film is exposed and developed in the manner described above. Afterward, the structure defined by the patterned photoresist is transferred into the layer of the mask material arranged below the photoresist in a first etching process. In this case, the plasma is chosen such that the patterned photoresist has a highest possible etch resistance with respect to the plasma, while the etch resistance of the mask material is low. After the fabrication of the mask, a second plasma is used to transfer the structure into the substrate arranged below the mask. The second plasma is chosen such that the etch resistance of the mask material is as high as possible, while the etch resistance of the substrate with respect to the plasma is as low as possible. Due to the small thickness of the photoresist layer, line collapse does not pose a problem when using multilayer resist systems or hard masks. What is disadvantageous, however, is that the use of such mask systems is significantly more complicated in comparison with single-layer photoresist systems since additional process steps are necessary for the patterning. In comparison with the use of single-layer photoresist systems, the latter processes incur increased costs in the manufacture of microchips. In light of the above, it is clear that there is a need for improved photoresist patterning methods for producing small features in a substrate.

### SUMMARY

An embodiment of the present invention provides a method for fabricating a resist mask for the patterning of semiconductor substrates which, with the use of single-layer resist systems, enables the critical feature size to be reduced further in comparison with known methods.

In an exemplary embodiment, a method for fabricating a resist mask for the patterning of semiconductor substrates includes providing a semiconductor substrate. In a further step, photoresist is applied on the semiconductor substrate, so that a photoresist film is obtained, after which the photoresist film is exposed, so that an exposed resist film is obtained. In a subsequent step a developer is applied to the exposed resist film, which strips the exposed resist film to produce a patterned resist film. In a preferred embodiment, a cationic surfactant is applied to the patterned resist film in the development step.

Subsequently, the developer is removed and the patterned resist film is dried, so that a resist mask is obtained.

The use of cationic surfactants makes it possible, for a given thickness of photoresist film, to significantly reduce the line width at which a line collapse is observed. It is believed that the capillary forces which act on the sidewalls of the webs of the patterned resist when evaporating the solvent during drying can be significantly reduced by the use of cationic surfactants. This makes it possible to reduce the line width of the webs without at the same time having to reduce the thickness of the photoresist layer. Therefore, thicker resist layers can be used even for a reduced line width, since the stability of the patterned resist with respect to a plasma suffices for transfer of the desired structure into the semiconductor substrate even in the case of a reduced critical feature size. The use of complicated multilayer resist systems or hard mask systems can therefore be avoided or delayed until it is necessary to pattern even smaller linewidths.

### BRIEF DESCRIPTION OF THE DRAWINGS

FIG. 1 depicts a diagrammatic illustration of a section through a resist structure, wherein a liquid is filled in a trench arranged between two resist features.

FIG. 2 is a diagram in which a dose leeway for the exposure dose of a photoresist is plotted against the thickness of the resist layer.

### DETAILED DESCRIPTION OF THE PREFERRED EMBODIMENTS

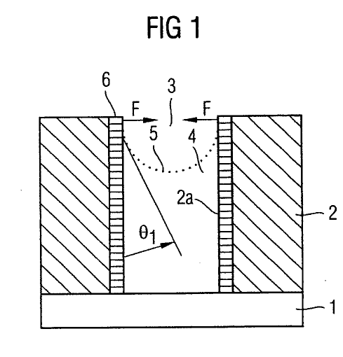

FIG. 1 diagrammatically shows a section through a patterned photoresist. Webs 2 made of a resist material are arranged on a substrate 1. A trench 3 is formed between webs 2, and filled with a rinsing medium 4, for example deionized water, after development. If rinsing medium 4 is evaporated during drying, a meniscus 5 forms at the surface of the rinsing medium 4. The meniscus is determined by the surface tension of the water and also the interface properties of sidewall 2a of resist webs 2. In this case, meniscus 5 forms a contact angle θ₁ with sidewall 2a. The capillary forces F acting on sidewall 2a are directly proportional to the interfacial surface tension or to the cosine of the contact angle θ (F proportional to G cos θ1). If rinsing medium 4 contains cationic surfactants, the latter form a layer 6 by virtue of which sidewall 2a of webs 2 acquires hydrophobic properties. Ideally, this sets a contact angle of θ₁=90° so that F=0. This corresponds to a hydrophobizing of surface 2a.

The following experimental results illustrate the operation of exemplary embodiments of the present invention.

### EXAMPLE

### Determining the Dose Leeway

Silicon wafers were coated with a commercially available chemically amplified positive photoresist. In this case, the layer thickness was set by means of the number of revolutions with which the photoresist was spun onto the wafer. Afterward, in a customary manner, the solvent contained in the photoresist was removed by heating the wafer and the photoresist layer was subjected to heat treatment by means of a short thermal treatment. The layer thickness of the resist film was set in a series of depositions to 310, 320, 330, 340 and 350 nm. Using a laser, a line pattern was imaged in each case onto the wafers prepared in this way, the line width corresponding to the critical feature size. The line pattern was created with a corresponding photomask arranged in the beam path of the laser, so that the line pattern defined in the photomask was projected on the resist film. The line pattern was imaged multiply onto the same resist film, the irradiation intensity having been varied systematically. The exposed wafer was in each case briefly subjected to heat treatment and then developed in the manner specified further below. The resist pattern obtained was subsequently examined by means of electron microscopy. The resulting resist feature size depends on the exposure dose. As the exposure dose increases, the line becomes narrower. Firstly, an exposure dose necessary to form a preset target line width in the resist film was determined. This exposure intensity corresponds to the value E_size. Furthermore, an (higher) exposure intensity at which a line collapse was observed was determined. This intensity is determined as E_collapse. The difference between E_size and E_collapse represents a “dose leeway” for processing the resist, within which the desired patterned resist linewidth can be obtained before a collapse occurs. For a given photomask, the line width depends on the intensity of the radiation which is used for imaging the photomask onto the resist layer. The higher the exposure intensity is chosen, the smaller becomes the line width of the resist webs obtained after development.

The exposed and heat-treated resist layers were developed as described below.

Development 1a: Conventional Rinsing Process.

A 2.38% strength solution of tetramethylammonium hydroxide in water was added to the exposed and heat-treated resist film and left there for 30 to 60 seconds. The developer was subsequently displaced from the surface of the resist film by rinsing with deionized water. For drying, the water remaining on the surface of the resist film was spun away from the wafer.

Development 1b: Surfactant Rinsing Process.

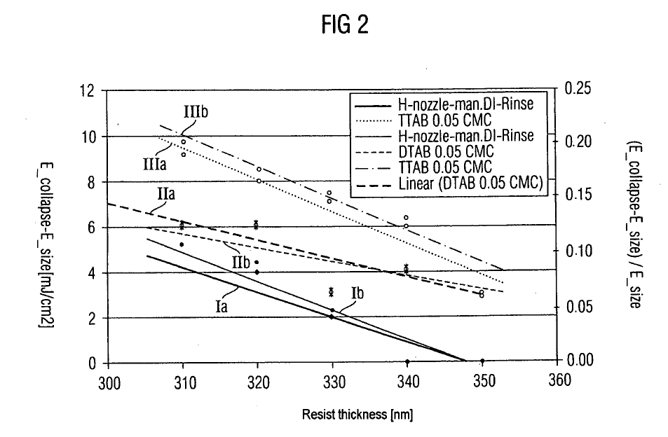

A solution of 2.38% tetramethylammonium hydroxide in water was added to the exposed and heat-treated resist film and left for 30 to 60 seconds on the surface of the wafer. The developer was subsequently displaced by rinsing with deionized water. A surfactant solution was subsequently added to the resist surface. The surfactant solution was left for 10 to 120 seconds on the surface of the wafer. During this time, the cationic surfactants are adsorbed on the surface of the resist. For drying, the surfactant solution was spun away from the wafer. Dodecyltrimethylammonium bromide (DTAB) and tetradecyltrimethylammonium bromide (TTAB) were used as surfactants. The results are illustrated in FIG. 2. The difference in the exposure intensity E_collapse-E_size (mJ/cm²) and the relative value (E_collapse-E_size)/E_size are in each case specified on the Y axis and the thickness of the photoresist film is specified on the X axis. The curves designated by “a” relate to “E_collapse-E_size” and the curves designated by “b” relate to “(E_collapse-E_size)/E_size”. In this case, the lines 1a and 1b correspond to the values which were obtained with the conventional rinsing process (Development 1a). It is evident that, at a resist thickness above 340 nm, the patterned structure can no longer be produced in the resist film. At layer thicknesses which are chosen to be greater than this value, a line collapse takes place.

The broken lines II and III correspond to values obtained when DTAB (curve IIa and IIb) and TTAB (curve IIIa and IIIb) were respectively applied to the patterned resist. It is evident that, given a layer thickness of approximately 348 nm, at which a line collapse was observed when using a conventional rinsing process, the resist lines retain their structure and damage to the resist lines is not observed. If the layer thickness is compared for the same dose leeway, then the thickness of the resist film can be increased by approximately 10% when using cationic surfactants.

Thus, embodiments of the present invention provide a method to achieve an improved stability of patterned resist using a simple lithographic process. Specifically, the procedure is such that firstly a semiconductor substrate is provided. The semiconductor substrate used is generally a silicon wafer, which may also already have undergone process steps and in which structure elements or microelectronic components may also already be integrated. The surface of the semiconductor substrate to be processed need not necessarily be formed by a semiconductor, for example silicon. Rather, it is also possible for a layer made of a dielectric into which structure elements are intended to be introduced to be applied on the surface of the semiconductor substrate. Therefore, there are no particular restrictions with regard to the semiconductor substrate used.

A film made of a photosensitive resist is subsequently applied on the semiconductor substrate, so that a photoresist film is obtained. Fabrication of the photoresist film is carried out by means of customary methods. Typically, the photoresist is spun on, that is to say that firstly a quantity of the photoresist is placed at the center of the semiconductor substrate, and the photoresist is distributed uniformly on the surface of the semiconductor substrate by rapid rotation of the semiconductor substrate. In this case, the layer thickness can be set by way of the rotational speed or by way of the duration of the spinning operation. Solvents contained in the photoresist are subsequently evaporated, for example, by heating momentarily the semiconductor substrate. The photoresist film may then also be subjected to heat treatment in order to obtain a resist film structure that is as homogeneous as possible.

Afterward, the photoresist film is exposed to produce an exposed resist film using conventional processing. Typically, the photoresist film is exposed by means of a beam from a laser which emits light having a suitable wavelength. A photomask is arranged in the beam path, through which photomask the structure is projected onto the resist film. However, it is also possible to write directly to the resist film for example by means of an electron beam. As a result of the exposure, the photoresist experiences a chemical change in the exposed sections, so that a differentiation between exposed and unexposed sections is achieved. In order to allow this chemical modification to proceed rapidly and completely, the exposed resist film or the semiconductor substrate may be heated momentarily to a suitable temperature.

Afterward, the exposed resist film is developed in a development step, either the exposed sections or the unexposed sections of the exposed resist film being removed. For this purpose, a suitable developer is placed onto the exposed resist film. The developer is generally an aqueous solution containing compounds which promote stripping of the modified sections of the exposed resist film. The developer is selected appropriately for the photoresist used, typically based on corresponding information made available by the manufacturers of photoresists. The developer strips sections of the exposed resist film, so that a patterned resist film is obtained. Depending on the photoresist used, either the exposed or the unexposed sections of the resist film are stripped in this case. Afterward, the developer is removed and the patterned resist film is dried, so that a resist mask is obtained.

According to an exemplary embodiment of the present invention, a cationic surfactant is applied to the patterned resist film in the development step. In this case, the cationic surfactant is applied in such a way that it can reduce the capillary forces acting on the resist webs during the drying of the patterned resist film. The cationic surfactant is thus applied to the patterned resist in such a way that it is contained in the solvent to be evaporated, usually water, at the beginning of the drying operation.

Preferably, the cationic surfactant is not added to the developer directly, since the substances contained in the developer usually cannot be evaporated without residues. Preferably, the developer is removed by being displaced with a rinsing medium. Usually, the procedure is such that firstly the majority of the developer is spun away from the surface of the semiconductor substrate. Afterward, the rinsing medium is added, usually water, which is then removed likewise by the predominant proportion thereof being spun away from the surface of the semiconductor substrate. Residues of the rinsing medium that remain in the patterned resist film are subsequently removed by drying.

The cationic surfactant may be contained in the rinsing medium. In this case, the quantity of the rinsing medium is chosen such that the developer is completely displaced.

Preferably, however, the procedure is such that the developer is removed with a deionized water rinsing medium in a first rinsing step, followed by use of an aqueous rinsing solution containing the cationic surfactant as a rinsing medium in a second rinsing step. In this way, it is possible minimize the quantity of surfactant required and to avoid interactions between the cationic surfactant and components of the developer.

Preferably, the rinsing solution containing the cationic surfactant is left on the patterned resist film for a duration of 10 to 120 seconds. The rinsing solution containing the cationic surfactant is applied to the patterned resist film as a liquid layer. During the time it remains on the patterned resist film, the cationic surfactants penetrate into the interspaces between webs or lines of the patterned resist film. It is believed that the cationic surfactant molecules are both adsorbed at the sidewalls of the resist webs and thereby cause said walls to be hydrophobized, and surfactant molecules are arranged at the surface of the rinsing solution contained in the trenches. This increases the contact angle of the rinsing solution at the interface with the resist web and thus also the capillary force acting on the sidewalls of the resist web.

The cationic surfactant used is preferably a surfactant which comprises a tertiary ammonium group. Such surfactants are available in great structural diversity and are sold commercially by numerous providers.

The cationic surfactants used are particularly preferably trimethylammonium salts whose alkyl group comprises more than 8 carbon atoms. Exemplary representatives of suitable trimethylammonium salts are dodecyltrimethylammonium salts, trimethyltetradecylammonium salts, hexadecyltrimethylammonium salts and octadecyltrimethylammonium salts.

The cationic surfactant is particularly preferably used as a bromide or hydrogensulfate.

The advantages of the method according to the invention are manifested in particular if the resist mask comprises structure elements having an aspect ratio of greater than 3.

Therefore, the photoresist film is particularly advantageously formed as a single-layer resist film. In this case, a single-layer resist film is understood to be a resist film which is essentially constructed homogeneously from an organic polymer. The single-layer resist film may be supplemented by an antireflection layer which can suppress reflections in the resist film.

Exemplary embodiments of the present invention include the use of negative photoresists as well as the use of positive photoresists. Positive photoresists are preferred, however. Positive photoresists generally have, in their polar form, negatively charged groups, such as carboxyl groups or deprotonatable hydroxyl groups. The webs obtained after development usually have polar properties on their side areas, since the side areas are usually formed by polymers in which only a proportion of the acid-labile groups have been cleaved. The polar components of these polymers then form the sidewalls of the resist webs. If a cationic surfactant is applied to such a resist, the surfactant molecules form a salt with the negatively charged groups on the sidewall of the resist web as a result of which the sidewall acquires significantly nonpolar properties. As a result, the contact angle which an aqueous solution forms with the sidewall of the resist web increases.

The photoresist is particularly preferably a chemically amplified resist. A chemically amplified photoresist is understood to be a photoresist which has a quantum efficiency of more than 1. This is achieved by virtue of the photoresist having a photoacid, on the one hand, and, on the other hand, the polar groups at the polymer being protected with a group which is cleaved under acid catalysis. A multiplicity of acid-labile groups can therefore be cleaved with an individual liberated proton. Embodiments of the present invention are particularly suitable for the fabrication of structures with a very small line width. Wavelengths of 248 nm, 193 nm or else 157 nm are suitable, by way of example. However, radiation having a wavelength of less than 100 nm can also be used for the exposure of the photoresist. Due to their charge properties, cationic surfactants may be used per se for any type of resist.

In order that the capillary forces acting on the sidewalls of the patterned resist are kept as small as possible, the concentration of the cationic surfactant in the rinsing medium is chosen such that a rinsing medium that remains in the trench arranged between webs of the patterned resist forms a contact angle 01 with the sidewall of the resist web of approximately 90°.

Furthermore, the concentration of the cationic surfactant in the rinsing medium is chosen to be less than the critical micelle concentration (CMC).

The foregoing disclosure of the preferred embodiments of the present invention has been presented for purposes of illustration and description. It is not intended to be exhaustive or to limit the invention to the precise forms disclosed. Many variations and modifications of the embodiments described herein will be apparent to one of ordinary skill in the art in light of the above disclosure. The scope of the invention is to be defined only by the claims appended hereto, and by their equivalents.

Further, in describing representative embodiments of the present invention, the specification may have presented the method and/or process of the present invention as a particular sequence of steps. However, to the extent that the method or process does not rely on the particular order of steps set forth herein, the method or process should not be limited to the particular sequence of steps described. As one of ordinary skill in the art would appreciate, other sequences of steps may be possible. Therefore, the particular order of the steps set forth in the specification should not be construed as limitations on the claims. In addition, the claims directed to the method and/or process of the present invention should not be limited to the performance of their steps in the order written, and one skilled in the art can readily appreciate that the sequences may be varied and still remain within the spirit and scope of the present invention.

What is claimed is:

1. A method for fabricating a resist mask for the patterning of semiconductor substrates, comprising:
providing a semiconductor substrate;
applying photosensitive resist on the semiconductor substrate, wherein a photoresist film is obtained;
exposing the photoresist film, wherein an exposed resist film is obtained;
developing the exposed resist film in a development step comprising:
applying a developer to the exposed resist film that strips the exposed resist film, so that a patterned resist film is obtained;
removing the developer;
applying a cationic surfactant to the patterned resist film; and
drying the patterned resist film, so that a resist mask is obtained.

2. The method of claim 1, wherein the developer is removed by being displaced by a rinsing medium.

3. The method of claim 2, wherein the cationic surfactant is contained in the rinsing medium.

4. The method of claim 2, wherein the developer is removed in a first rinsing step using deionized water as a rinsing medium, and wherein the cationic surfactant is contained in an aqueous rinsing solution used as rinsing medium in a second rinsing step.

5. The method of claim 4, wherein the rinsing solution containing the cationic surfactant is left on the patterned resist film for a duration of 10 to 120 seconds.

6. The method of claim 1, wherein the cationic surfactant comprises a tertiary ammonium group.

7. The method of claim 1, wherein the cationic surfactant is a trimethylalkylammonium salt whose alkyl group comprises more than 8 carbon atoms.

8. The method of claim 1, wherein the cationic surfactant is used as a bromide or hydrogensulfate.

9. The method of claim 1, wherein the photoresist film is formed as a single-layer resist film.

10. The method of claim 1, wherein the photoresist is a positive photoresist.

11. The method of claim 1, wherein the photoresist is a chemically amplified photoresist.

12. The method of claim 1, wherein the resist mask comprises structure elements having an aspect ratio of greater than 3.

13. The method of claim 1, wherein the exposure is effected by means of radiation having a wavelength of less than 200 nm.

14. The method of claim 1, wherein the concentration of the cationic surfactant in the rinsing medium is chosen such that a rinsing medium that has remained in a trench arranged between webs of the patterned resist forms a contact angle θ₁ with the sidewall of the resist web of approximately 90°.

15. The method of claim 1, wherein the concentration of the cationic surfactant in the rinsing medium is less than the critical micelle concentration (CMC).

16. A method for forming a patterned resist layer comprising:
providing a substrate;
applying a resist layer to the substrate;
selectively exposing the resist layer to form a set of unexposed resist regions and a set of exposed resist regions;
developing the resist layer using a developer, wherein one of the sets of regions chosen from the set of unexposed regions and the set of exposed regions is removed, wherein a patterned resist layer is formed;
exposing the patterned resist layer to a cationic surfactant; and
drying the resist layer, wherein a resist mask is formed.

17. The method of claim 16, further comprising displacing the developer using a first rinsing medium.

18. The method of claim 17, wherein the first rinsing medium includes a cationic surfactant.

19. The method of claim 17, further comprising adding a second rinsing medium after the first rinsing medium, wherein the second rinsing medium includes an aqueous solution of a cationic surfactant.

20. The method of claim 19, wherein the first rinsing medium consists essentially of deionized water.
